(19) United States
(12) Patent Application Publication
(10) Pub. No.: US 2025/0151549 A1
(43) Pub. Date: May 8, 2025

(54) DISPLAY PANEL AND METHOD OF REPAIRING THE SAME

(71) Applicant: Samsung Display Co., Ltd., Yongin-si (KR)

(72) Inventors: SUNKWANG KIM, Yongin-si (KR); MOON-KEUN CHOI, Yongin-si (KR); DONG-YOON LEE, Yongin-si (KR); SEONGYOUNG LEE, Yongin-si (KR); KANGMOON JO, Yongin-si (KR)

(21) Appl. No.: 18/798,727

(22) Filed: Aug. 8, 2024

(30) Foreign Application Priority Data
Nov. 6, 2023 (KR) 10-2023-0151545

(51) Int. Cl. H10K 59/131; H10K 59/12; H10K 59/121; H10K 59/122; H10K 59/38; H10K 71/00

(52) U.S. Cl. CPC H10K 59/131; H10K 59/1201; H10K 59/1213; H10K 59/122; H10K 59/38; H10K 71/861

(57) ABSTRACT

Provided is a display panel including a base layer, data lines, a first power supply line, a sensing line, first to third pixel circuits comprising first to third transistors, a scan line, a first light-emitting element overlapping the first pixel circuit, a second light-emitting element overlapping the second pixel circuit and connected to the second pixel circuit, and a third light-emitting element overlapping the data lines. The third pixel circuit is disconnected from the third light-emitting element and connected to the first light-emitting element, and at least any one of semiconductor patterns comprised in the first transistor, the second transistor, or the third transistor of the first pixel circuit is disconnected.

### CROSS-REFERENCE TO RELATED APPLICATION

This application claims priority to, and the benefit of, Korean Patent Application No. 10-2023-0151545, filed on Nov. 6, 2023, the entire contents of which are hereby incorporated by reference.

### BACKGROUND

### 1. Field

The present disclosure herein relates to a display panel including a circuit element with improved reliability, and a method of repairing the same.

### 2. Description of the Related Art

A display panel includes a plurality of pixels and a driving circuit (for example, a scan-driving circuit and a data-driving circuit) for controlling the plurality of pixels. Each of the plurality of pixels includes a display element, and a pixel-driving circuit for controlling the display element. The pixel-driving circuit may include a plurality of transistors, which are organically connected, and at least one capacitor.

### SUMMARY

The present disclosure provides a display panel with improved display quality, and a method of repairing the same.

One or more embodiments of the present disclosure provides a display panel including a base layer, data lines above the base layer, arranged along a first direction, and extending along a second direction crossing the first direction, a first power supply line extending along the first direction, a sensing line spaced apart from the first power supply line in the second direction, and extending along the first direction, a first pixel circuit, a second pixel circuit, and a third pixel circuit including a first transistor, a second transistor, and a third transistor including semiconductor patterns, at least one of the semiconductor patterns of the first pixel circuit being disconnected, a scan line spaced apart from the sensing line in the second direction with the first pixel circuit, the second pixel circuit, and the third pixel circuit therebetween, and extending along the first direction, a first light-emitting element overlapping the first pixel circuit, and connected to the third pixel circuit, a second light-emitting element overlapping the second pixel circuit and connected to the second pixel circuit, and a third light-emitting element overlapping the data lines, and disconnected from the third pixel circuit.

The third light-emitting element may be disconnected from the first pixel circuit and the second pixel circuit, and is not configured to emit light, wherein the first light-emitting element and the second light-emitting element are configured to emit light.

The first light-emitting element, the second light-emitting element, and the third light-emitting element may include a first electrode, a second electrode above the first electrode, and a common layer between the first electrode and the second electrode, wherein the common layer and the second electrode are commonly located in the first light-emitting element, the second light-emitting element, and the third light-emitting element.

The display panel may further include a pixel-defining layer above the base layer, and defining openings exposing the first electrodes and including a first opening defining a first light-emitting region, a second opening defining a second light-emitting region, and third opening defining a third light-emitting region.

The first electrode of the third light-emitting element may be disconnected.

In plan view, the first electrode of the third light-emitting element may be disconnected and divided into a first portion and a second portion extending in the second direction along one long side of the third opening, wherein the first portion is connected to the third pixel circuit, and wherein the second portion is disconnected from the third pixel circuit.

The scan line may include a scan pattern along the second direction and overlapping one of the semiconductor patterns in the second transistor.

The scan pattern may include a first pattern overlapping the second transistor of the first pixel circuit, and a second pattern disconnected from the first pattern and overlapping the second transistor of the second pixel circuit and the second transistor of the third pixel circuit.

One end of the first portion may be connected to the first pattern via a first repair hole in the first pattern, wherein the first electrode of the first light-emitting element is connected to the first pattern via a second repair hole spaced apart from the first repair hole.

The first electrode of the first light-emitting element may be connected to the third pixel circuit via the first pattern and the first portion.

The display panel may further include a light control layer above the first light-emitting element, the second light-emitting element, and the third light-emitting element, wherein the light control layer includes color control layers include quantum dots, and color patterns above the color control layers.

The first light-emitting element may be configured to generate light to pass through the light control layer to provide blue light, wherein the second light-emitting element is configured to generate light to pass through the light control layer to provide green light.

In one or more embodiments of the present disclosure, a method of repairing a display panel includes forming a first pixel circuit, a second pixel circuit, and a third pixel circuit including a first transistor, a second transistor, and a third transistor, forming a scan line including a scan pattern overlapping semiconductor patterns in the second transistor, checking signals of the first pixel circuit, the second pixel circuit, and the third pixel circuit, disconnecting semiconductor patterns in the first transistor, the second transistor, and the third transistor of the first pixel circuit, dividing the scan pattern into a first pattern overlapping the second transistor of the first pixel circuit, and a second pattern overlapping the second transistor of the second pixel circuit and the second transistor of the third pixel circuit, forming an organic insulating layer covering the first pixel circuit, the second pixel circuit, and the third pixel circuit, forming, in the organic insulating layer, a first repair hole and a second repair hole overlapping the first pattern, forming first electrodes overlapping the first pixel circuit, the second pixel circuit, and the third pixel circuit on the organic insulating layer, dividing the first electrode overlapping the third pixel circuit into a first portion connected to the third pixel circuit, and a second portion spaced apart from the third pixel circuit, and connecting the third pixel circuit to the first electrode overlapping the first pixel circuit.

The connecting the third pixel circuit to one of the first electrodes overlapping the first pixel circuit may include irradiating the first repair hole and the second repair hole with a laser.

The one of the first electrodes overlapping the first pixel circuit may be in the first repair hole and is connected to the first pattern, wherein the first portion is in the second repair hole and is connected to the first pattern.

The method may further include forming on the organic insulating layer a pixel-defining layer defining a first opening, a second opening, and a third opening respectively exposing portions of the first electrodes.

A boundary between the first portion and the second portion may be formed along one side of the third opening overlapping the third pixel circuit in plan view.

The method may further include forming a common layer on the first electrodes, and forming a second electrode on the common layer.

The first opening overlapping one of the first electrodes connected to the third pixel circuit may be configured to emit light, wherein the second opening overlapping another one of the first electrodes connected to the second pixel circuit is configured to emit light, and wherein the third opening overlapping an additional one of the first electrodes overlapping the third pixel circuit is not configured to emit light.

The second opening and the third opening may be spaced apart from each other along a first direction in which the scan line extends, wherein the first opening is spaced apart from the second opening along a second direction crossing the first direction.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A is a perspective view of a display panel according to one or more embodiments of the present disclosure;

FIG. 1B is a perspective view of a curved display panel according to one or more embodiments of the present disclosure;

FIG. 2A is a cross-sectional view of a display panel according to one or more embodiments of the present disclosure;

FIG. 2B is a plan view of a display panel according to one or more embodiments of the present disclosure;

FIG. 3 is an equivalent circuit diagram of a pixel according to one or more embodiments of the present disclosure;

FIGS. 4A and 4B are enlarged plan views of a display region according to one or more embodiments of the present disclosure;

FIG. 5 is a plan view according to a stacking order of conductive patterns included in a unit pixel according to one or more embodiments of the present disclosure;

FIG. 6 is a cross-sectional view taken along the line I-I′ of FIG. 5;

FIGS. 7A to 7I are plan views illustrating, for each layer, a stacking order of conductive patterns included in a unit pixel according to one or more embodiments of the present disclosure;

FIG. 8 is an equivalent circuit diagram illustrating a repair process of one pixel included in a unit pixel according to one or more embodiments of the present disclosure;

FIGS. 9A to 9C are plan views illustrating a repair process of conductive patterns included in a unit pixel according to one or more embodiments of the present disclosure; and

FIG. 10 is a cross-sectional view taken along the line II-II′ of FIG. 9C.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

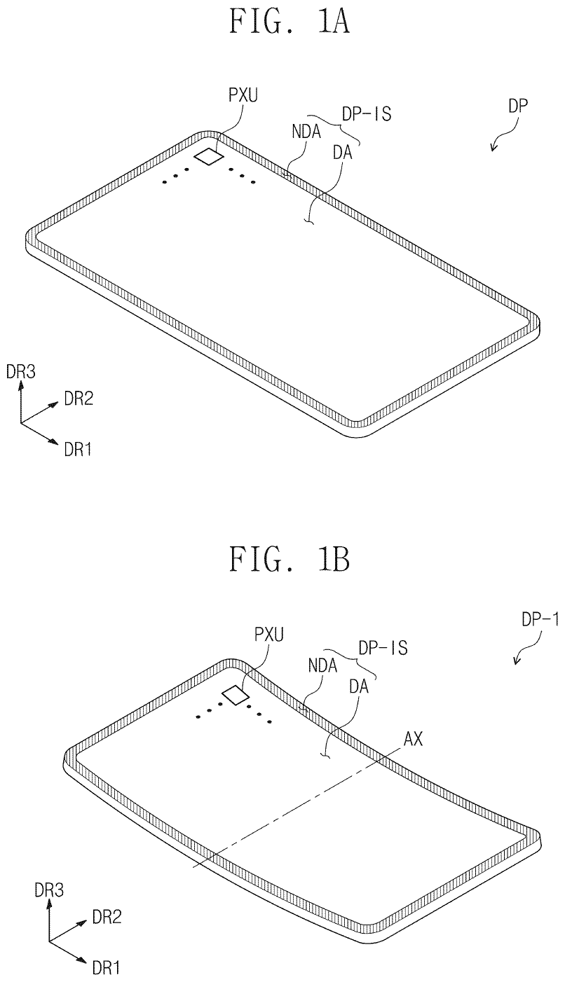

FIG. 1A is a perspective view of a display panel according to one or more

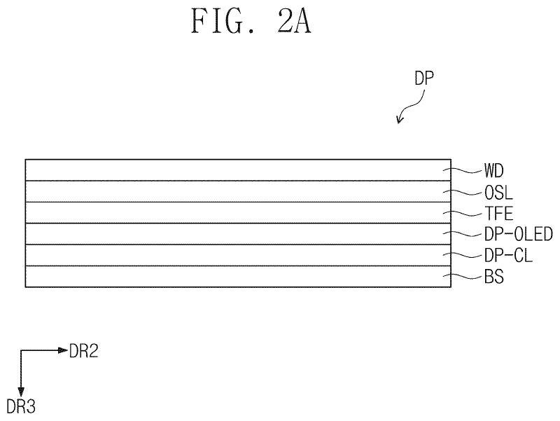

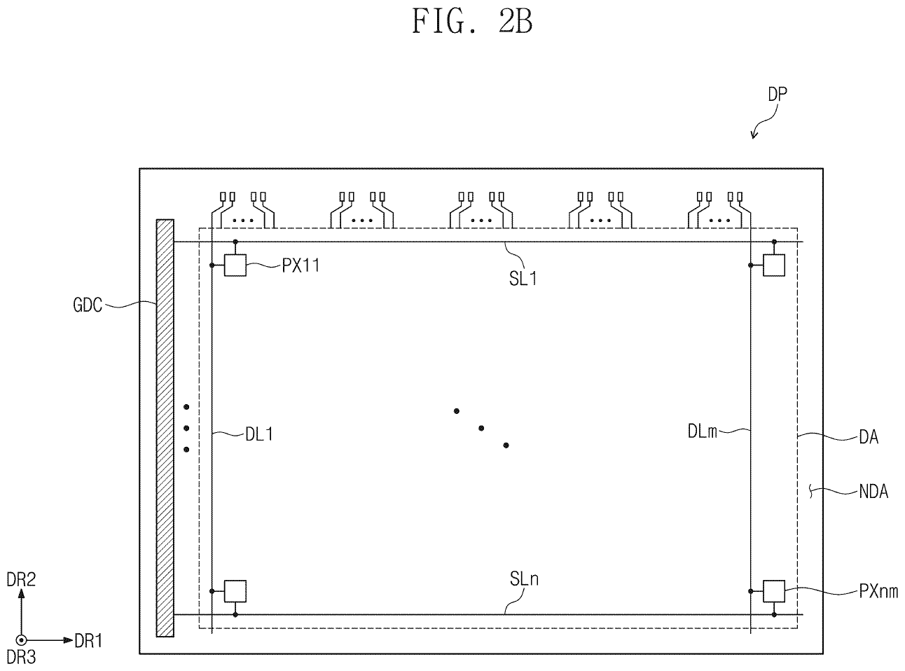

embodiments of the present disclosure. FIG. 1B is a perspective view of a curved display panel according to one or more embodiments of the present disclosure. FIG. 2A is a cross-sectional view of a display panel according to one or more embodiments of the present disclosure. FIG. 2B is a plan view of a display panel according to one or more embodiments of the present disclosure.

A display surface DP-IS may be parallel to a plane defined by a first direction DR1 and by a second direction DR2. A normal direction of the display surface DP-IS, that is, a thickness direction of a display panel DP indicates a third direction DR3. A front surface (or a top surface) and a rear surface (or a bottom surface) of each layer or each unit described below are distinguished based on the third direction DR3.

The display panel DP may include a display region DA and a non-display region NDA. A light-emitting layer included in each of pixels PX11 to PXnm (see FIG. 2B) is located in the display region DA, and the light-emitting layer of each of the pixels PX11 to PXnm (see FIG. 2B) is not located in the non-display region NDA. The non-display region NDA is defined along an edge of the display surface DP-IS. The non-display region NDA may surround the display region DA. In one or more embodiments of the present disclosure, the non-display region NDA may be omitted, or may be located only on one side of the display region DA.

Referring to FIG. 1B, a display panel DP-1 according to one or more embodiments may be curved along the first direction DR1 with respect to an imaginary axis AX extending in the second direction DR2. However, one or more embodiments of the present disclosure is not limited thereto, and the axis may extend in the first direction DR1, or the display panel may be curved with respect to a plurality of axes extending in different directions.

The display panels DP and DP-1 according to one or more embodiments may be a rollable display panel, a foldable display panel, or a slidable display panel. Here, the display panels DP and DP-1 may have a flexible property, and may be folded or rolled while being installed on a display device. Accordingly, the display panels DP and DP-1 may include a curved display surface or a three-dimensional display surface DP-IS. The three-dimensional display surface DP-IS may include a plurality of display regions indicating directions which are different from each other.

According to one or more embodiments, unit pixels PXU that are arranged along the first direction DR1 and the second direction DR2 may be located on the display surface DP-IS. One unit pixel PXU may include at least two pixels PX11 to PXnm (see FIG. 2B) that generate source light.

An emission area, shape, and arrangement form of each of the pixels PX11 to PXnm (see FIG. 2B) included in one unit pixel PXU are not limited to any embodiment. For example, the pixels included in the unit pixel PXU may respectively have different emission areas. In addition, light-emitting regions may each have a circular shape or a polygonal shape on a plane.

Referring to FIGS. 2A and 2B, the display panel DP according to one or more embodiments of the present disclosure may include a base layer BS, a circuit element layer DP-CL located on the base layer BS, a display element layer DP-OLED, an encapsulation layer TFE, a light control layer OSL, and a window panel WD. The display panel DP may further include functional layers, such as an anti-reflective layer, a refractive index adjustment layer, or the like. The circuit element layer DP-CL may include at least a plurality of insulating layers and a circuit element. The insulating layers to be described below may include an organic layer and/or an inorganic layer.

The base layer BS may include a synthetic resin layer. The synthetic resin layer may include a thermosetting resin. For example, the synthetic resin layer may include at least any one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, an organic/inorganic composite material substrate, or the like.

For the circuit element layer DP-CL, an insulating layer, a semiconductor layer, and a conductive layer are formed through a process, such as coating and deposition. Then, the insulating layer, the semiconductor layer, and the conductive layer may be selectively patterned through a photolithography and an etching process. A semiconductor pattern, a conductive pattern, a signal line, or the like may be formed through such processes. Patterns located on the same layer may be formed through the same process.

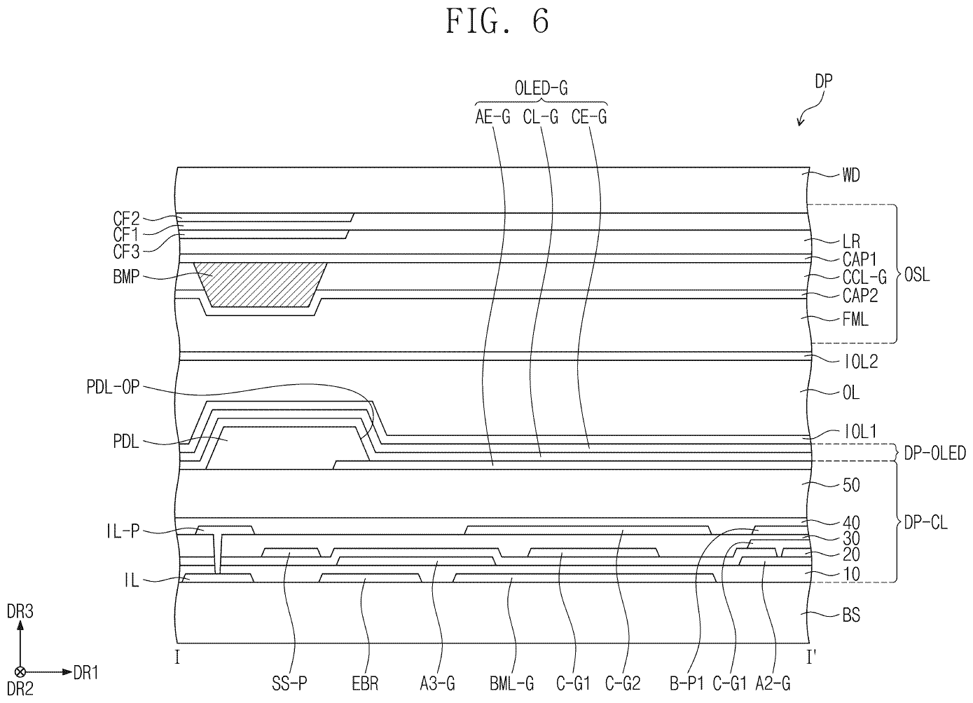

The circuit element layer DP-CL may include a driving circuit or a signal line connected to the pixels PX11 to PXnm (see FIG. 2B). The display element layer DP-OLED may include a light-emitting element OLED and a pixel-defining layer PDL (see FIG. 6).

The encapsulation layer TFE may be located on the display element layer DP-OLED, and may protect the light-emitting element OLED. The encapsulation layer TFE may include inorganic layers, and an organic layer located between the inorganic layers. The inorganic layers may protect the light-emitting element OLED from moisture and oxygen, and the organic layer may protect the light-emitting element OLED from foreign materials, such as dust particles.

The light control layer OSL may include light control patterns, which are capable of converting the optical properties of source light generated in the pixels PX11 to PXnm (see FIG. 2B). The light control patterns may include quantum dots, and also include color filters that selectively transmit light that passes through the light control patterns.

The window panel WD may be located in an upper portion of the display panel DP, and may transmit an image, which is provided from the display panel DP to the outside. In the window panel WD, the display region DA and the non-display region NDA of the display surface DP-IS may be distinguished from each other, as illustrated in FIG. 1A. A boundary between the display region DA and the non-display region NDA may be located under the window panel WD, and may be defined by a bezel pattern that absorbs light.

The window panel WD may include a base layer, and functional layers located on the base layer. The functional layers may include a protective layer, an anti-fingerprint layer, or the like. The base layer of the window panel WD may be composed of glass, sapphire, plastic, or the like.

FIG. 2B illustrates a planar arrangement relationship of signal lines SL1 to SLn and DL1 to DLm and the pixels PX11 to PXnm which are included in the display panel DP. The signal lines SL1 to SLn and DL1 to DLm may include a plurality of scan lines SL1 to SLn and a plurality of data lines DL1 to DLm.

The pixels PX11 to PXnm may be located in the display region DA. The pixels PX11 to PXnm may each be connected to a corresponding scan line among the plurality of scan lines SL1 to SLn and a corresponding data line among the plurality of data lines DL1 to DLm. The pixels PX11 to PXnm may each include a pixel-driving circuit and a light-emitting element. The display panel DP may be equipped with more types of signal lines depending on a configuration of the pixel-driving circuit of each of the pixels PX11 to PXnm.

A gate-driving circuit GDC may be located in the non-display region NDA. The gate-driving circuit GDC may be integrated in the display panel DP through an oxide silicon gate driver circuit (OSG) process or an amorphous silicon gate driver circuit (ASG) process.

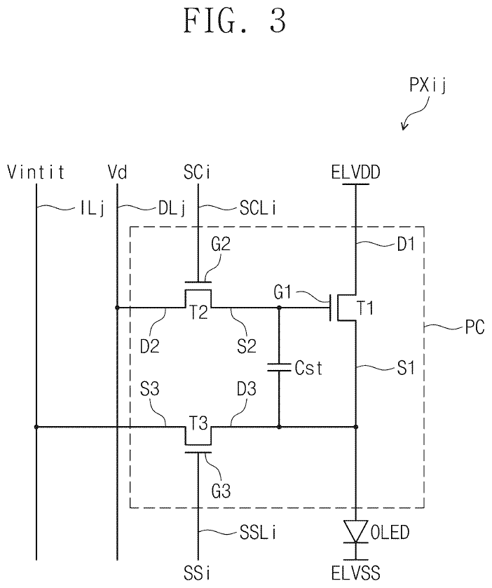

FIG. 3 illustrates a circuit diagram of one pixel PXij among the pixels PX11 to PXnm. Three pixels PXij may be located in one unit pixel PXU illustrated in FIG. 1A. The pixels PXij may each include a pixel circuit PC and a light-emitting element OLED to be described later. The pixel circuit PC may include a plurality of transistors T1, T2, and T3 and a capacitor Cst.

The plurality of transistors T1, T2, and T3 may be formed through a low temperature polycrystalline silicon (LTPS) process or a low temperature polycrystalline oxide (LTPO) process. First to third transistors T1, T2, and T3 may each include either one of a silicon semiconductor or an oxide semiconductor. Here, although not limited to any embodiment, the oxide semiconductor may include a crystalline or amorphous oxide semiconductor, and the silicon semiconductor may include amorphous silicon, polycrystalline silicon, or the like.

Hereinafter, the first to third transistors T1, T2, and T3 will be described as having an n-type, but one or more embodiments of the present disclosure is not limited thereto. Each of the first to third transistors T1, T2, and T3 may be a p-type transistor or an n-type transistor depending on an applied signal. Here, the source and drain of the p-type transistor may correspond to the drain and source of the n-type transistor, respectively.

FIG. 3 illustrates a pixel PXij that is connected to an i-th scan line SCLi, an i-th sensing line SSLi, a j-th data line DLj, and a j-th initial line ILj.

The pixel circuit PC may include the first transistor T1 (a driving transistor), the second transistor T2 (a switch transistor), the third transistor T3 (a sensing transistor), and a capacitor Cst. However, the pixel circuit PC may further include an additional transistor and an additional capacitor, and is not limited.

The light-emitting element OLED may be an organic light-emitting element or an inorganic light-emitting element, which include an anode (a first electrode) and a cathode (a second electrode). The anode (a first voltage) of the light-emitting element OLED may receive a first voltage ELVDD via the first transistor T1, and the cathode (a second voltage) of the light-emitting element OLED may receive a second voltage ELVSS. The light-emitting element OLED may emit light by receiving the first voltage ELVDD and the second voltage ELVSS.

The first transistor T1 may include a drain D1 receiving the first voltage ELVDD, a source S1 connected to the anode of the light-emitting element OLED, and a gate G1 connected to the capacitor Cst. The first transistor T1 may control driving current flowing from the first voltage ELVDD to the light-emitting element OLED based on a voltage value stored in the capacitor Cst.

The second transistor T2 may include a drain D2 connected to the j-th data line DLj, a source S2 connected to the capacitor Cst, and a gate G2 for receiving an i-th first scan signal SCi. The second transistor T2 provides a data voltage Vd to the first transistor T1 in response to the i-th first scan signal SCi.

The third transistor T3 may include a source S3 connected to the j-th initial line ILj, a drain D3 connected to the anode of the light-emitting element OLED, and a gate G3 receiving an i-th second scan signal SSi. The j-th initial line ILj may receive an initial voltage Vintit.

The capacitor Cst may store a voltage difference of various values depending on an input signal. For example, the capacitor Cst may store a voltage corresponding to a difference between the first voltage ELVDD and the voltage received from the second transistor T2.

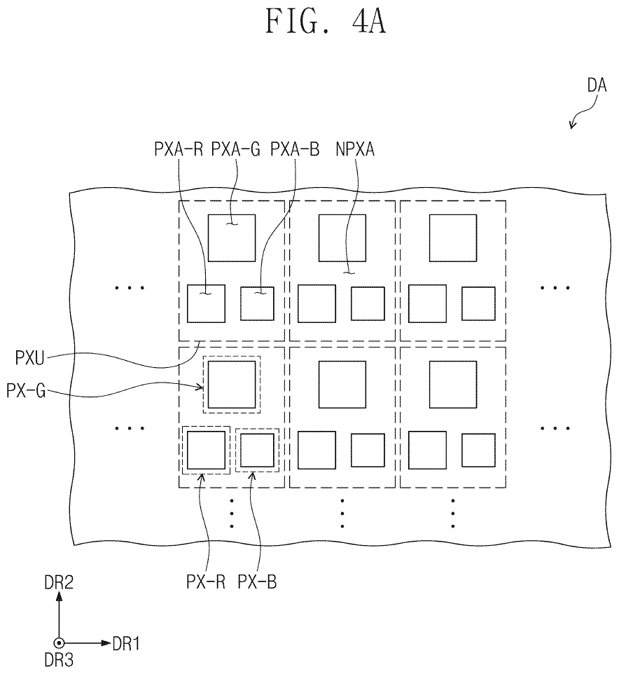

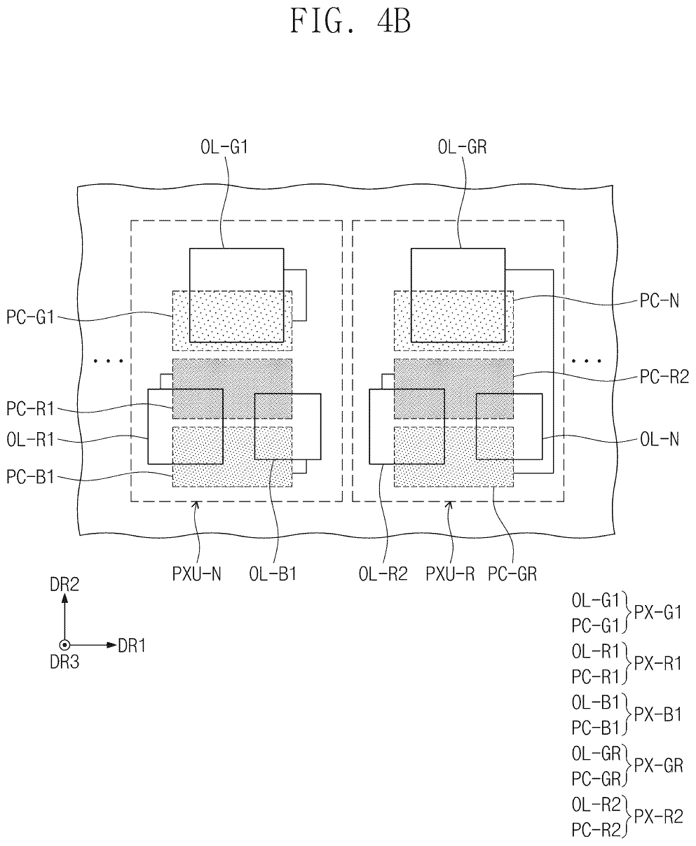

Referring to FIG. 4A, source light formed in a first pixel PX-G may be provided to a first pixel region PXA-G, source light formed in a second pixel PX-R may be provided to a second pixel region PXA-R, and source light formed in a third pixel PX-B may be provided to a third pixel region PXA-B. The first to third pixel regions PXA-G, PXA-R, and PXA-B may respectively correspond to openings PDL-OP (see FIG. 6) defined in a pixel-defining layer PDL (see FIG. 6).

In FIG. 4A, shapes of first electrodes AE-G (see FIG. 6), which are respectively included in the first to third pixels PX-G, PX-R, and PX-B, are referred to as shapes of the first to third pixels PX-G, PX-R, and PX-B for convenience of explanation.

The first to third pixels PX-G, PX-R, and PX-B may each include a light-emitting element OLED (see FIG. 6), and the light-emitting elements OLED may emit source light of the same color. For example, the source light may be blue light. The source light generated in the light-emitting elements OLED (see FIG. 6) may be converted into any one of red light, green light, or blue light through the light control patterns included in the light control layer OSL illustrated in FIG. 2A. The converted light may be emitted through the first pixel region PXA-G, the second pixel region PXA-R, and the third pixel region PXA-B. When passing through the light control layer OSL, green light may be provided to the first pixel region PXA-G, red light may be provided to the second pixel region PXA-R, and blue light may be provided to the third pixel region PXA-B. However, one or more embodiments of the present disclosure is not limited thereto, and the source light generated in the first to third pixels PX-G, PX-R, and PX-B may have different colors.

According to one or more embodiments, the second pixel region PXA-R and the third pixel region PXA-B are located in the same row, and the first pixel region PXA-G is located in a row that is different from the row where the second pixel region PXA-R and the third pixel region PXA-B are located. For example, the second pixel region PXA-R may be spaced apart from the third pixel region PXA-B along the first direction DR1, and the first pixel region PXA-G may be spaced apart from the second pixel region PXA-R and the third pixel region PXA-B in respective diagonal directions (e.g., diagonal to the first direction DR1 and the second direction DR2). According to one or more embodiments, an area of the first pixel region PXA-G may be smaller than that of the second pixel region PXA-R, and may be greater than that of the third pixel region PXA-B.

The first pixel region PXA-G, the second pixel region PXA-R, and the third pixel region PXA-B are illustrated as having a square shape, but arrangement forms and areas of the pixel regions are not limited thereto.

The arrangement structure of the first pixel region PXA-G, the second pixel region PXA-R, and the third pixel region PXA-B within the unit pixel PXU illustrated in FIG. 4A is merely an example, and is not limited thereto. For example, the first pixel region PXA-G, the second pixel region PXA-R, and the third pixel region PXA-B may be arranged along the first direction DR1 and located in the same row. In addition, the arrangement of the first pixel region PXA-G, the second pixel region PXA-R, and the third pixel region PXA-B in each of the unit pixels PXU may not necessarily be the same.

FIG. 4B illustrates a normal unit pixel PXU-N in a normal state, and a repair unit pixel PXU-R. In this specification, the repair unit pixel PXU-R may be defined as a state in which one of the first to third pixels PX-G, PX-R, and PX-B included in one unit pixel PXU is defective, and the defective pixel is repaired.

The normal unit pixel PXU-N may include first to third normal pixels PX-G1, PX-R1, and PX-B1. The first to third normal pixels PX-G1, PX-R1, and PX-B1 may correspond to the first to the third pixels PX-G, PX-R, and PX-B illustrated in FIG. 4A.

The first normal pixel PX-G1 may include a first normal pixel circuit PC-G1 and a first normal light-emitting element OL-G1 connected thereto. The second normal pixel PX-R1 may include a second normal pixel circuit PC-R1 and a second normal light-emitting element OL-R1 connected thereto. The third normal pixel PX-B1 may include a third normal pixel circuit PC-B1 and a third normal light-emitting element OL-B1 connected thereto.

That is, the first to third normal pixel circuits PC-G1, PC-R1, and PC-B1 included in the normal unit pixel PXU-N may be connected to the first to third normal light-emitting elements OL-G1, OL-R1, and OL-B1 in a one-to-one correspondence.

The first to third normal pixel circuits PC-G1, PC-R1, and PC-B1 may each correspond to the pixel circuit PC illustrated in FIG. 3, and the first to third normal light-emitting elements OL-G1, OL-R1, and OL-B1 may each correspond to a light-emitting element OLED-G in FIG. 6. FIG. 4B illustrates that the shapes of the first to third normal pixel circuits PC-G1, PC-R1, and PC-B1 are rectangular shapes extending in the first direction DR1, for convenience of explanation.

The repair unit pixel PXU-R may include a repair pixel PX-GR, a second normal pixel PX-R2, a disconnection pixel circuit PC-N, and a disconnection light-emitting element OL-N. Any one of the pixels included in the normal unit pixel PXU-N may emit source light after being repaired from a defective state. Semiconductor patterns included in a pixel circuit of a defective pixel may be disconnected.

For example, the semiconductor patterns included in the disconnection pixel circuit PC-N may be disconnected. In this specification, the disconnection pixel circuit PC-N may be a defective pixel circuit among the pixel circuits due to a short circuit defect, or the like, as may be determined through a signal inspection test. Here, a state in which the semiconductor patterns included in the defective pixel circuit are disconnected may be defined as the disconnection pixel circuit PC-N. According to the present disclosure, the disconnection pixel circuit PC-N may be floated without being connected to any of the light-emitting elements located in the repair unit pixel PXU-R.

After a manufacturing process of the display panel is performed, a repair light-emitting element OL-GR and a repair pixel circuit PC-GR may be connected so as to drive the repair light-emitting element OL-GR, which should have been connected to the existing disconnection pixel circuit PC-N. The repair pixel circuit PC-GR may correspond to the third normal pixel circuit PC-B1 in the normal unit pixel PXU-N, and may be a pixel circuit for substantially driving the disconnection light-emitting element OL-N. After a repair process is performed, the repair pixel circuit PC-GR may be connected to the repair light-emitting element OL-GR, and may drive the repair light-emitting element OL-GR.

According to the present disclosure, the disconnection light-emitting element OL-N may cut a first electrode AE-G (see FIG. 6) included in the disconnection light-emitting element OL-N, and may connect the repair light-emitting element OL-GR to the repair pixel circuit PC-GR by connecting, among the cut part, a portion connected to the repair pixel circuit PC-GR, to the first electrode AE-G (see FIG. 6) of the repair light-emitting element OL-GR.

Accordingly, when the display panel DP is operated, the disconnection light-emitting element OL-N included in the repair unit pixel PXU-R may become a dark spot, and the disconnection pixel circuit PC-N may be spaced apart from the light-emitting elements to be in a floating state. A process for connecting the repair light-emitting element OL-GR to the repair pixel circuit PC-GR through the repair process may be performed through a laser process. This will be described later.

According to the present disclosure, source light which is generated in the first normal pixel PX-G1 and the repair pixel PX-GR may pass through the light control layer OSL (see FIG. 2A) and may be provided to a user as green light. Source light generated in the second normal pixels PX-R1 and PX-R2 may pass through the light control layer OSL (see FIG. 2A) and may be provided to a user as red light. Source light generated in the third normal pixel PX-B1 may pass through the light control layer OSL (see FIG. 2A) and may be provided to a user as blue light. According to the present disclosure, when the display panel is operated, the disconnection light-emitting element OL-N within the repair unit pixel PXU-R may become a dark spot.

For example, when a pixel providing green light becomes a dark spot, blue light and red light may be provided from one unit pixel, and thus be viewed as magenta light by a user. For another example, when a pixel providing blue light becomes a dark spot, green light and red light may be provided from one unit pixel, and thus be viewed as yellow light by a user. Because magenta light is more visible, or noticeable, than yellow light by a user in a large display panel DP (see FIG. 1A), it may be suitable to repair the pixel providing green light and cause the pixel providing blue light become a dark spot in the repair unit pixel PXU-R.

According to the present disclosure, because the pixel providing green light is repaired and the pixel providing blue light becomes a dark spot in the repair unit pixel PXU-R, a yield of the repair process and the reliability of the display panel DP may be improved.

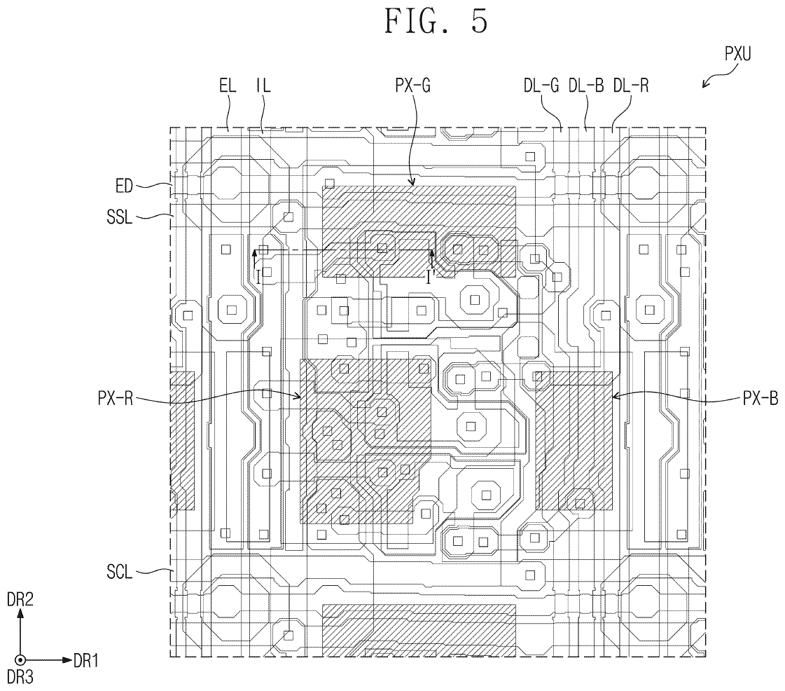

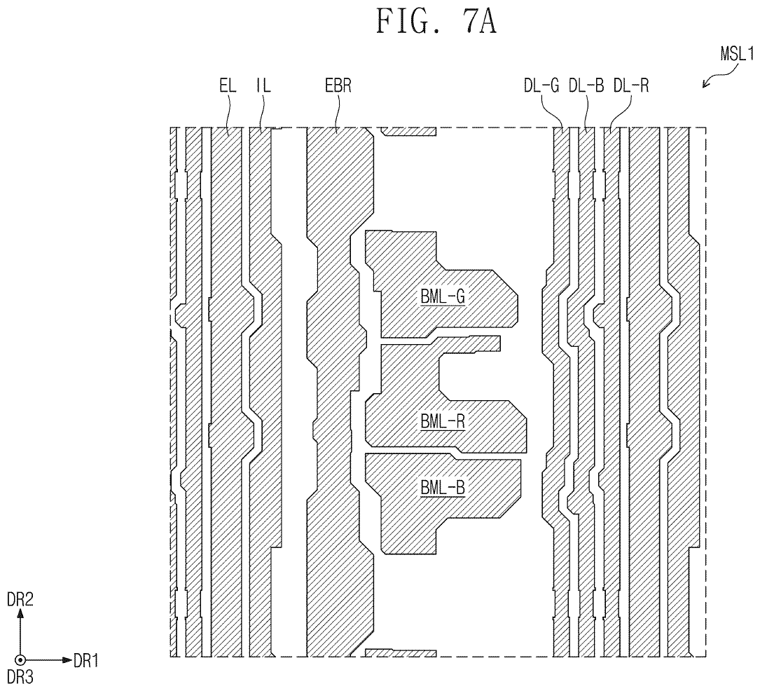

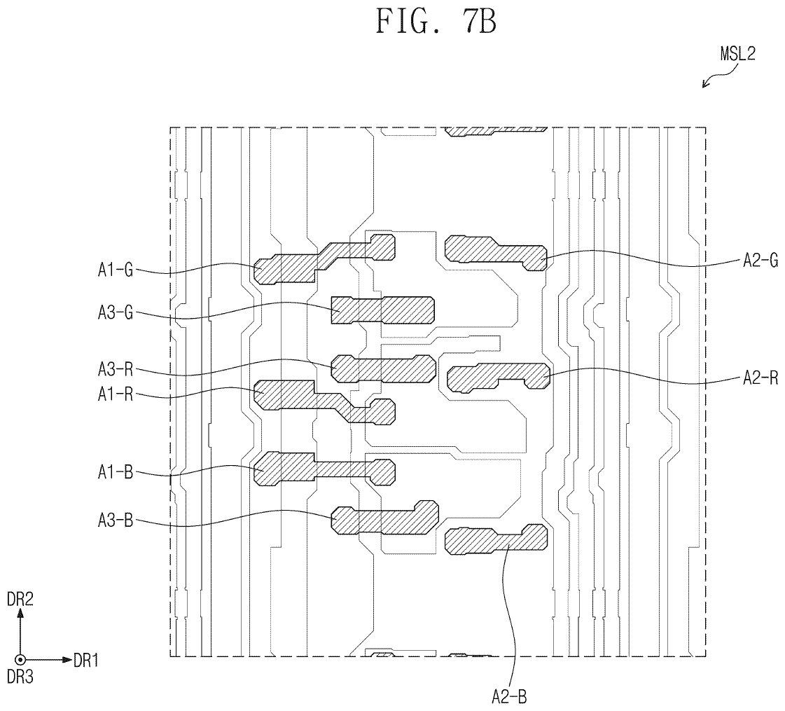

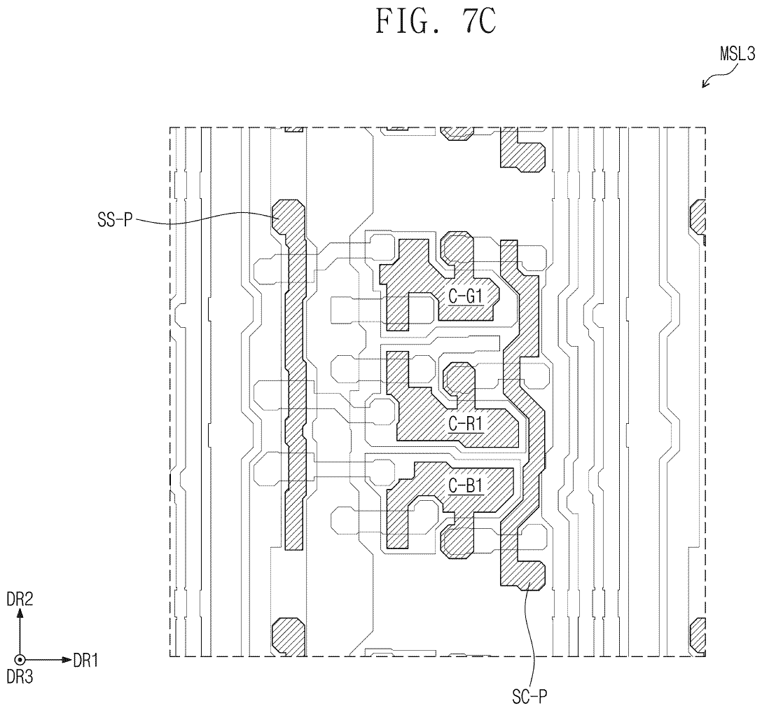

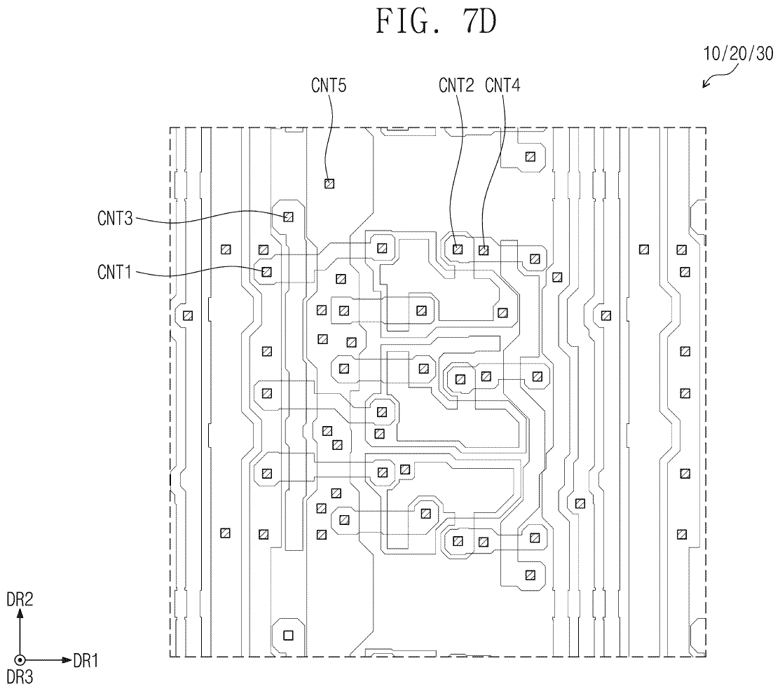

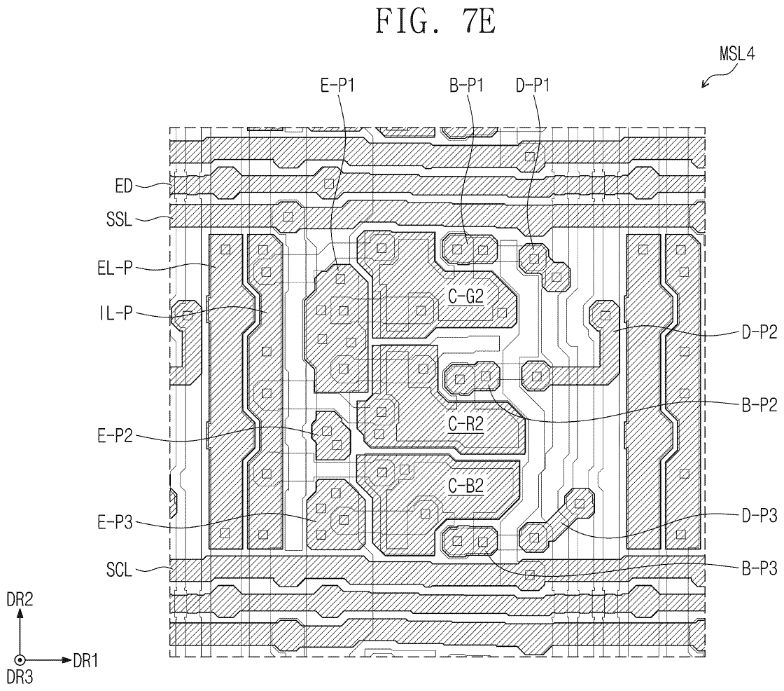

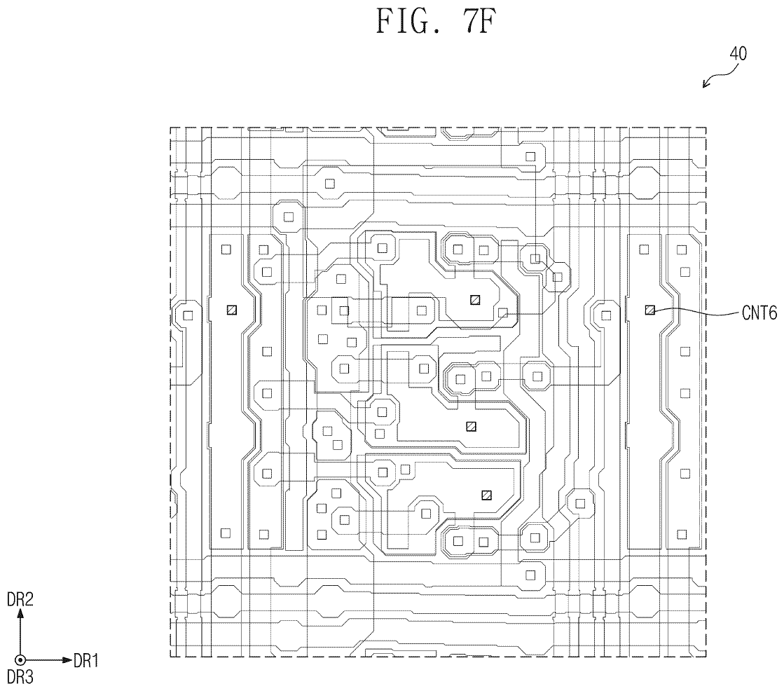

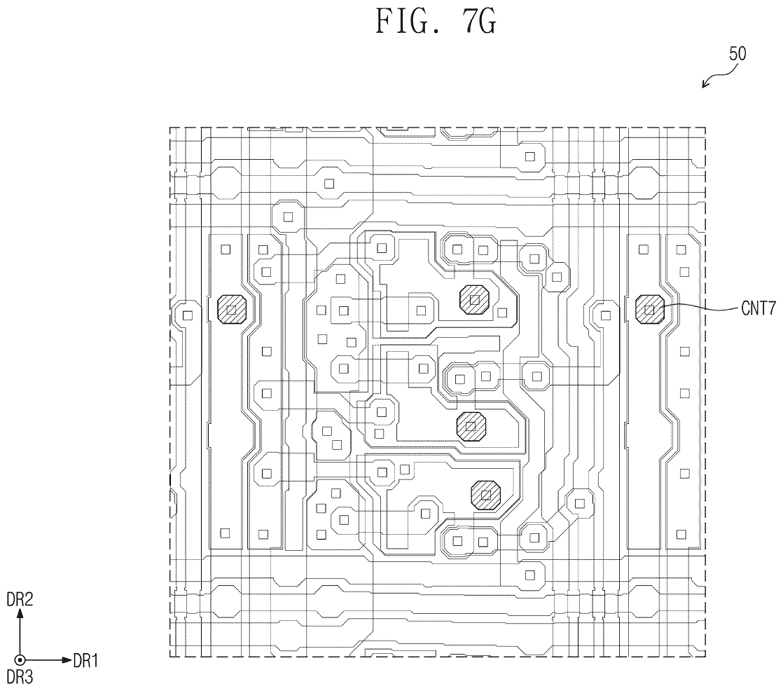

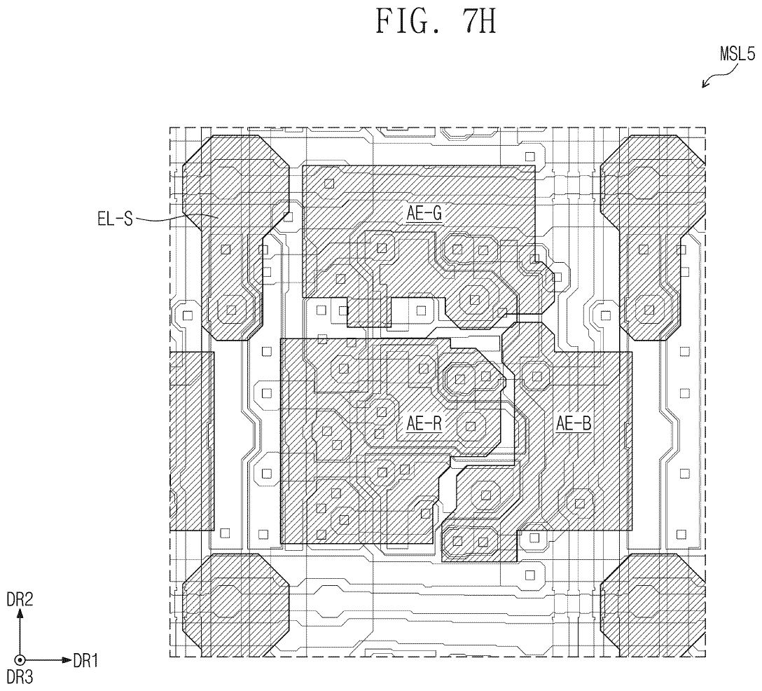

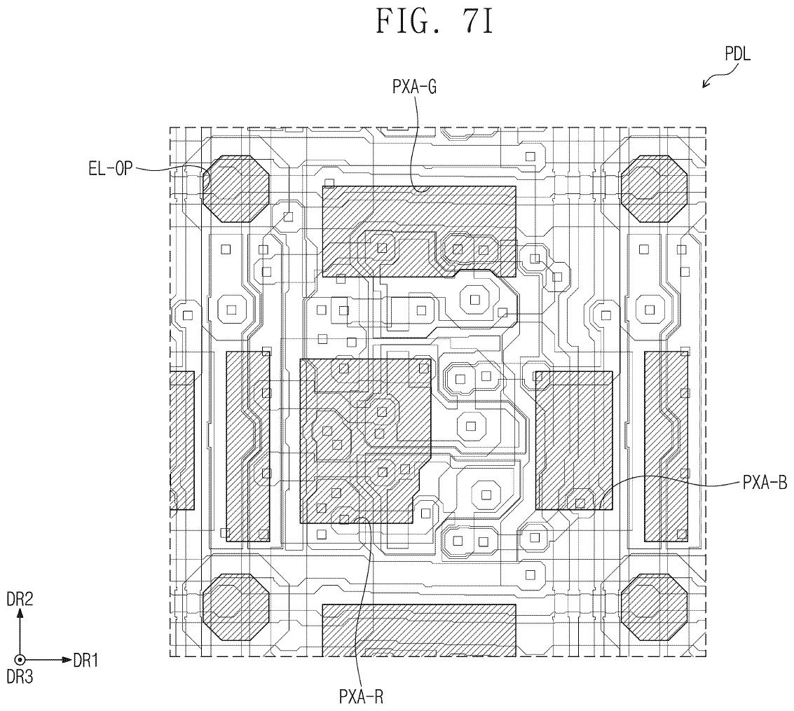

FIG. 5 is a plan view according to a stacking order of conductive patterns included in a unit pixel according to one or more embodiments of the present disclosure. FIG. 6 is a cross-sectional view taken along the line I-I′ of FIG. 5. FIGS. 7A to 7I are plan views illustrating, for each layer, a stacking order of conductive patterns included in a unit pixel according to one or more embodiments of the present disclosure.

Referring to FIG. 5, one unit pixel PXU may include first to third pixels PX-G, PX-R, and PX-B. The first to third pixels PX-G, PX-R, and PX-B may each include the pixel circuit PC and the light-emitting element OLED, which have been described with reference to FIG. 3.

The first to third pixels PX-G, PX-R, and PX-B may each be connected to a first power supply line ED, a second power supply line EL, an initial line IL, a scan line SCL, and a sensing line SSL. In addition, the first to third pixels PX-G, PX-R, and PX-B may be connected to corresponding data lines DL-G, DL-R, and DL-B, respectively. The first power supply line ED may provide the first voltage ELVDD (see FIG. 3), and the second power supply line EL may provide the second voltage ELVSS (see FIG. 3), which is lower than the first voltage ELVDD.

According to one or more embodiments, the data lines DL-G, DL-R, and DL-B, the initial line IL, and the second power supply line EL may be spaced apart from each other along the first direction DR1, and may each extend along the second direction DR2. The first power supply line ED, the sensing line SSL, and the scan line SCL may be spaced apart from each other along the second direction DR2, and may each extend along the first direction DR1. The first power supply line ED may be spaced apart from the scan line SCL along the second direction DR2 with the sensing line SSL therebetween. Pixel circuits included in the first to third pixels PX-G, PX-R, and PX-B may be located between the sensing line SSL and the scan line SCL.

Referring to FIG. 6, a display panel DP according to one or more

embodiments may include a base layer BS, a circuit element layer DP-CL located on (as used herein, “on” may mean “above”) the base layer BS, a display element layer DP-OLED, an encapsulation layer TFE, a light control layer OSL, and a window panel WD.

The circuit element layer DP-CL is located on the base layer BS. The circuit element layer DP-CL may include insulating layers 10, 20, 30, 40, and 50 located on the base layer BS, and conductive patterns IL, IL-P, SS-P, EBR, A3-G, BML-G, C-G1, C-G2, B-P1, and A2-G located between the insulating layers 10, 20, 30, 40, and 50. According to one or more embodiments, first to fourth insulating layers 10, 20, 30, and 40 may each be provided as an inorganic layer. The first to fourth insulating layers 10, 20, 30, and 40 may each be provided as a single layer of an inorganic layer or multiple layers including different inorganic layers, but are not limited to any embodiment. Fifth insulating layer 50 may be provided as an organic layer. Repair holes may be formed by penetrating portions of the fifth insulating layer 50 and at least one of the inorganic insulating layers located under the fifth insulating layer 50 during the aforementioned repair process. The conductive patterns IL-P1, IL-P2, SS-P, EBR, A3, BML-G, C-G1, C-G2, B-P1, and A2-G will be described later.

A first light-shielding pattern BML-G may be connected to a source of a first transistor T1 included the first pixel PX-G, may receive a signal applied to the source, and may form a sync structure under a semiconductor pattern. The first light-shielding pattern BML-G may receive a bias voltage while overlapping a first active pattern. The first light-shielding pattern BML-G may also receive the first voltage ELVDD (see FIG. 3).

The first light-shielding pattern BML-G may reduce or prevent the effect of electrical potential on the first transistor T1 otherwise caused by polarization. In addition, the first light-shielding pattern BML-G may reduce or prevent external light reaching the first transistor T1. In one or more embodiments of the present disclosure, the first light-shielding pattern BML-G may be a floating electrode that is isolated from other electrodes or wires. The description related to the first light-shielding pattern BML-G may also be applied to second and third light-shielding patterns BML-R and BML-B to be described in FIG. 7A. The other conductive patterns will be described in detail later.

The display element layer DP-OLED may include a pixel-defining layer PDL in which openings PDL-OP respectively corresponding to the pixel regions PXA-G, PXA-R, and PXA-B described with reference to FIG. 4A are defined, and a light-emitting element OLED-G. The light-emitting element OLED-G illustrated in FIG. 6 may be included in the first pixel PX-G described with reference to FIG. 4A.

According to one or more embodiments, the pixel-defining layer PDL may have light-absorbing properties, and for example, the pixel-defining layer PDL may have a black color. The pixel-defining layer PDL may include a black coloring agent. The black coloring agent may include a black dye and a black pigment. The black coloring agent may include carbon black, metal, such as chrome, or an oxide thereof. The pixel-defining layer PDL may correspond to a light-shielding pattern which has light-shielding properties.

A first electrode AE-G of the first light-emitting element OLED-G may be located on the fifth insulating layer 50. A second electrode CE-G may be located on/above the first electrode AE-G. A common layer CL-G may be located between the first electrode AE-G and the second electrode CE-G. The common layer CL-G may include a light-emitting layer having an organic material, a hole control layer located between the first electrode AE-G and the light-emitting layer, and an electron control layer located between the light-emitting layer and the second electrode CE-G. The hole control layer may include a hole transport layer and a hole injection layer. The electron control layer may include an electron transport layer and an electron injection layer. According to one or more embodiments, the common layer CL-G may be a common layer which is commonly formed in the first to third pixels PX-G, PX-R, and PX-B.

The encapsulation layer TFE may cover the display element layer DP-OLED. The encapsulation layer TFE may include an organic material or an inorganic material. The encapsulation layer TFE may have a multi-layered structure in which an inorganic layer/an organic layer are repeated. The encapsulation layer TFE may include a first inorganic layer IOL1, an organic layer OL, and a second inorganic layer IOL2, which are sequentially stacked. The first and second inorganic layers IOL1 and IOL2 may protect the light-emitting element OLED from external moisture, and the organic layer OL may reduce or prevent the likelihood of the light-emitting element OLED being dented due to foreign materials introduced during the manufacturing process.

The first and second inorganic layers IOL1 and IOL2 may include a silicon nitride layer, a silicon oxynitride layer, a silicon oxide layer, a titanium oxide layer, an aluminum oxide layer, or the like. The first and second inorganic layers IOL1 and IOL2 may each have a multi-layered structure. The organic layer OL may include an acrylate-based organic layer, but is not limited thereto. The inorganic layers may protect the first light-emitting element OLED-G from moisture and oxygen, and the organic layer OL may protect the first light-emitting element OLED-G from foreign materials, such as dust particles.

The light control layer OSL may be located on the encapsulation layer TFE. The light control layer OSL may be located between the encapsulation layer TFE and the window panel WD. A rear surface of the window panel WD may provide a base surface on which components included in the light control layer OSL are formed. The components included in the light control layer OSL will be described in the order in which the components are formed in the rear surface of the window panel WD for convenience of explanation.

A color filter layer CFL may be located on the rear surface of the window panel WD. The color filter layer CFL may include a first color filter CF1 that transmits first light, a second color filter CF2 that transmits second light, and a third color filter CF3 that transmits source light. In one or more embodiments, the first color filter CF1 may be a green filter, the second color filter CF2 may be a red filter, and the third color filter CF3 may be a blue filter.

The first to third color filters CF1, CF2, and CF3 may each include a polymer photosensitive resin and a colorant. The first color filter CF1 may include a green colorant, the second color filter CF2 may include a red colorant, and the third color filter CF3 may include a blue colorant. The first color filter CF1 may include a green pigment or a green dye, the second color filter CF2 may include a red pigment or a red dye, and the third color filter CF3 may include a blue pigment or a blue dye.

The first to third color filters CF1, CF2, and CF3 may correspond to the first pixel region PXA-G, the second pixel region PXA-R, and the third pixel region PXA-B, respectively. That is, the first to third color filters CF1, CF2, and CF3 may overlap the corresponding openings PDL-OP, respectively. In addition, the first to third color filters CF1, CF2, and CF3 may correspond to first to third color control layers, respectively. FIG. 6 shows the color control layer CCL-G overlapping the first color filter CF1 as an example.

In addition, the plurality of color filters CF1, CF2, and CF3, which transmit different light, may overlappingly correspond to peripheral regions located between the first to third pixel regions PXA-R, PXA-B, and PXA-G. The plurality of color filters CF1, CF2, and CF3 may overlap each other in the third direction DR3, which is a thickness direction, and boundaries between the adjacent light-emitting regions may be distinguished. Meanwhile, unlike what is illustrated, the color filter layer CFL may include a light-shielding part, which distinguishes boundaries between the adjacent first to third color filters CF1, CF2, and CF3. The light-shielding part may be formed as a blue filter, or may be formed including an organic light-shielding material or an inorganic light-shielding material, which contains a black pigment or a black dye.

A low refractive layer LR may be located between first to third color control layers and the color filter layer CFL. The low refractive layer LR may cover the first to third color filters CF1, CF2, and CF3.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin-film of which a light transmittance is ensured, or the like. However, one or more embodiments of the present disclosure is not limited thereto, and the low refractive layer LR may include an organic film. The low refractive layer LR may have, for example, a structure in which a plurality of hollow particles are dispersed in an organic polymer resin. The low refractive layer LR may be composed of a single layer or multiple layers.

The low refractive layer LR may cover a barrier layer CAP1. According to one or more embodiments, the barrier layer CAP1 may be provided as a plurality of inorganic layers. The barrier layer CAP1 may reduce or prevent the color control layer CCL-G being permeated by moisture/oxygen, and may increase the durability of the film.

A bank BMP may be located under the barrier layer CAP1. The bank BMP may include a base resin and an additive. The base resin may be composed of various resin compositions generally referred to as a binder. The additive may include a coupling agent and/or a photoinitiator. The additive may further include a dispersant. The bank BMP may include a black coloring agent to block light. The bank BMP may include a black dye and a black pigment, which are mixed in the base resin. In one or more embodiments, the black coloring agent may include carbon black, or may include a metal, such as chrome or an oxide thereof.

The bank BMP may include a bank opening corresponding to the opening PDL-OP. The color control layer CCL-G may be located in the bank opening. The color control layer CCL-G may include quantum dots for changing the optical properties of source light. The color control layer CCL-G may include quantum dots that convert source light into light of a different wavelength. In the color control layer CCL-G, the quantum dots may convert blue light, which is the source light, into green light. According to one or more embodiments, quantum dots for converting blue source light into red light may be included in the bank opening which overlaps the second color filter CF2.

An additional barrier layer CAP2 may cover the bank BMP and the color control layer CCL-G. The additional barrier layer CAP2 may be provided as an inorganic layer. The additional barrier layer CAP2 may seal the bank BMP and the color control layers together with the barrier layer CAP1.

A filling layer FML may be located between the additional barrier layer CAP2 and the encapsulation layer TFE. The filling layer FML may function as a buffer between the display element layer DP-OLED and the light control layer OSL. According to one or more embodiments, the filling layer FML may perform a shock-absorbing function, or the like, and may increase the intensity of the display panel DP. The filling layer FML may be formed from a filling resin including a polymer resin. For example, the filling layer FML may be formed from a filling resin including an acrylate-based resin, an epoxy-based resin, or the like.

The filling layer FML is a component which is separate from both the encapsulation layer TFE located thereunder and the additional barrier layer CAP2 located thereupon, and may thus be formed in a process operation separate from those for the encapsulation layer TFE and the additional barrier layer CAP2. Meanwhile, the filling layer FML may be formed of a material that is different from those of the encapsulation layer TFE and the additional barrier layer CAP2.

FIGS. 7A to 7I illustrate a stacking order of conductive patterns included in a unit pixel PXU on which a repair process is not performed.

Referring to FIGS. 5, 6, and 7A, a first conductive layer MSL1 may be located on the base layer BS, and may be covered by the first insulating layer 10.

The first conductive layer MSL1 may include a second power supply line EL, an initial line IL, a power supply line EBR, first to third light-shielding patterns BML-G, BML-R, and BML-B, and first to third data lines DL-G, DL-R, and DL-B.

The second power supply line EL, the initial line IL, and the power supply line EBR may be arranged along the first direction DR1 and may extend along the second direction DR2. The initial line IL may be located between the second power supply line EL and the power supply line EBR.

The first to third light-shielding patterns BML-G, BML-R, and BML-B may be spaced apart from each other along the second direction DR2. The first to third light-shielding patterns BML-G, BML-R, and BML-B may be located between the power supply line EBR and the first data line DL-G.

The first to third data lines DL-G, DL-R, and DL-B may be arranged along the first direction DR1, and may extend along the second direction DR2. The third data line DL-B may be located between the first data line DL-G and the second data line DL-R.

Referring to FIGS. 5, 6, and 7B, a second conductive layer MSL2 may be located on the first insulating layer 10, and may be covered by the second insulating layer 20.

The second conductive layer MSL2 may include first to third active patterns A1-G, A2-G, and A3-G included in the first pixel PX-G, first to third active patterns A1-R, A2-R, and A3-R included in the second pixel PX-R, first to third active patterns A1-B, A2-B, and A3-B included in the third pixel PX-B, and a third capacitor pattern C-B.

Referring to FIGS. 5, 6, and 7C, a third conductive layer MSL3 may be located on the second insulating layer 20, and may be covered by the third insulating layer 30.

The third conductive layer MSL3 may include a sensing pattern SS-P, a scan pattern SC-P, and first to third lower capacitor patterns C-G1, C-R1, and C-B1. The sensing pattern SS-P may be connected to a sensing line SSL (see FIG. 7E) to be described later, and may be a portion protruding from the sensing line SSL along the second direction DR2.

The scan pattern SC-P may be connected to a scan line SCL (see FIG. 7E) to be described later, and may be a portion protruding from the scan line SCL along the second direction DR2.

The first to third lower capacitor patterns C-G1, C-R1, and C-B1 may be arranged along the second direction DR2. The first to third lower capacitor patterns C-G1, C-R1, and C-B1 may overlap the corresponding first to third light-shielding patterns BML-G, BML-R, and BML-B, respectively. The first to third lower capacitor patterns C-G1, C-R1, and C-B1 may overlap first to third upper capacitor patterns C-G2, C-R2, and C-B2, to be described in FIG. 7E, and may define the capacitor Cst described with respect to FIG. 3.

FIG. 7D illustrates contact holes CNT1, CNT2, CNT3, CNT4, and CNT5, which are defined by passing through at least any one of the first to third insulating layers 10, 20, or 30, described in FIG. 6.

First contact holes CNT1 may be defined by passing through the first insulating layer 10. The first contact holes CNT1 may connect conductive patterns located on the first conductive layer MSL1 and the second conductive layer MSL2.

Second contact holes CNT2 may be defined by passing through the second insulating layer 20. The second contact holes CNT2 may connect conductive patterns located on the second conductive layer MSL2 and the third conductive layer MSL3.

Third contact holes CNT3 may be defined by passing through the third insulating layer 30. The third contact holes CNT3 may connect conductive patterns located on the third conductive layer MSL3 and a fourth conductive layer MSL4 to be described in FIG. 7E.

Fourth contact holes CNT4 may be defined by passing through the second insulating layer 20 and the third insulating layer 30. The fourth contact holes CNT4 may connect conductive patterns located on the second conductive layer MSL2 and the fourth conductive layer MSL4 to be described in FIG. 7E.

Fifth contact holes CNT5 may be defined by passing through the first insulating layer 10, the second insulating layer 20, and the third insulating layer 30. The fifth contact holes CNT5 may connect conductive patterns located on the first conductive layer MSL1 and the fourth conductive layer MSL4 to be described in FIG. 7E.

Referring to FIGS. 5, 6, and 7E, a fourth conductive layer MSL4 may be located on the third insulating layer 30, and may be covered by the fourth insulating layer 40.

The fourth conductive layer MSL4 may include a first power supply line ED, a sensing line SSL, a scan line SCL, a power supply pattern EL-P, an initial pattern IL-P, first to third power supply line patterns E-P1, E-P2, and E-P3, first to third upper capacitor patterns C-G2, C-R2, and C-B2, first to third bridge patterns B-P1, B-P2, and B-P3, and first to third data patterns D-P1, D-P2, and D-P3.

The first power supply line ED, the sensing line SSL, and the scan line SCL may be arranged along the second direction DR2, and may extend along the first direction DR1. The sensing line SSL may be located between the first power supply line ED and the scan line SCL. The pixel circuits PC described in FIG. 3 may be located between the sensing line SSL and the scan line SCL.

The power supply pattern EL-P may overlap the second power supply line EL, and may be connected to the second power supply line EL via the fifth contact holes CNT5.

The initial pattern IL-P may overlap the initial line IL, and may be connected to the initial line IL via the fifth contact holes CNT5.

The first to third power supply line patterns E-P1, E-P2, and E-P3 may overlap the power supply line EBR. The first to third power supply line patterns E-P1, E-P2, and E-P3 may be spaced apart from each other along the second direction DR2. The first to third power supply line patterns E-P1, E-P2, and E-P3 may be connected to the power supply line EBR via the fifth contact holes CNT5.

The first power supply line pattern E-P1 may be connected to the third active patterns A3-G and A3-R via the fourth contact holes CNT4. The third power supply line pattern E-P3 may be connected to the third active pattern A3-B via the fourth contact holes CNT4.

The first to third upper capacitor patterns C-G2, C-R2, and C-B2 may overlap the corresponding first to third lower capacitor patterns C-G1, C-R1, and C-B1, respectively.

The first to third bridge patterns B-P1, B-P2, and B-P3 may respectively connect the second active patterns A2-G, A2-R, and A2-B to the first to third lower capacitor patterns C-G1, C-R1, and C-B1.

One end of the first bridge pattern B-P1 may be connected to the first lower capacitor pattern C-G1 via the third contact hole CNT3, and the other end of the first bridge pattern B-P1 may be connected to the second active pattern A2-G via the fourth contact hole CNT4.

One end of the second bridge pattern B-P2 may be connected to the second lower capacitor pattern C-R1 via the third contact hole CNT3, and the other end of the second bridge pattern B-P2 may be connected to the second active pattern A2-R via the fourth contact hole CNT4.

One end of the third bridge pattern B-P3 may be connected to the third lower capacitor pattern C-B1 via the third contact hole CNT3, and the other end of the third bridge pattern B-P3 may be connected to the second active pattern A2-B via the fourth contact hole CNT4.

The first to third data patterns D-P1, D-P2, and D-P3 may connect the second active patterns A2-G, A2-R, and A2-B to the first to third data lines DL-G, DL-R, and DL-B.

One end of the first data pattern D-P1 may be connected to the second active pattern A2-G via the fourth contact hole CNT4, and the other end of the first data pattern D-P1 may be connected to the first data line DL-G via the fifth contact hole CNT5.

One end of the second data pattern D-P2 may be connected to the second active pattern A2-R via the fourth contact hole CNT4, and the other end of the second data pattern D-P2 may be connected to the second data line DL-R via the fifth contact hole CNT5.

One end of the third data pattern D-P3 may be connected to the second active pattern A2-B via the fourth contact hole CNT4, and the other end of the third data pattern D-P3 may be connected to the third data line DL-B via the fifth contact hole CNT5.

FIG. 7F illustrates sixth contact holes CNT6 which are defined by passing through the fourth insulating layer 40 described with reference to FIG. 6. The sixth contact holes CNT6 may overlap the power supply pattern EL-P and the first to third upper capacitor patterns C-G2, C-R2, and C-B2.

FIG. 7G illustrates seventh contact holes CNT7 which are defined by passing through the fifth insulating layer 50 described with reference to FIG. 6. The seventh contact holes CNT7 may overlap the sixth contact holes CNT6. The fifth insulating layer 50 may be provided as an organic layer.

Referring to FIGS. 5, 6, and 7H, a fifth conductive layer MSL5 may be located on the fifth insulating layer 50, and may be covered by the pixel-defining layer PDL.

The fifth conductive layer MSL5 may include first electrodes AE-G, AE-R, and AE-B which are included in the respective pixels. The first electrodes AE-G, AE-R, and AE-B may be connected to first to third upper capacitor electrodes C-G2, C-R2, and C-B2, respectively, via the corresponding sixth and seventh contact holes CNT6 and CNT7.

The fifth conductive layer MSL5 may further include an additional power supply pattern EP-S. The additional power supply pattern EP-S may be connected to the power supply pattern EL-P via the corresponding sixth and seventh contact holes CNT6 and CNT7.

FIG. 7I illustrates the pixel-defining layer PDL described with reference to FIG. 6. The openings PDL-OP described with reference to FIG. 6 are shown in dark hatching for convenience of explanation. The openings OP (see FIG. 6) that expose at least a portion of each of the first electrodes AE-G, AE-R, and AE-B may be defined in the pixel-defining layer PDL. The openings OP (see FIG. 6) may correspond to the first to third pixel regions PXA-G, PXA-R, and PXA-B. The first to third pixel regions PXA-G, PXA-R, and PXA-B may be regions in which source light generated in the first to third pixels PX-G, PX-R, and PX-B is provided

An additional opening EL-OP that exposes at least a portion of the additional power supply pattern EP-S may be defined in the pixel-defining layer PDL. The second electrode CE-G (see FIG. 6) may be located in the additional opening EL-OP and connected to the second power supply line EL.

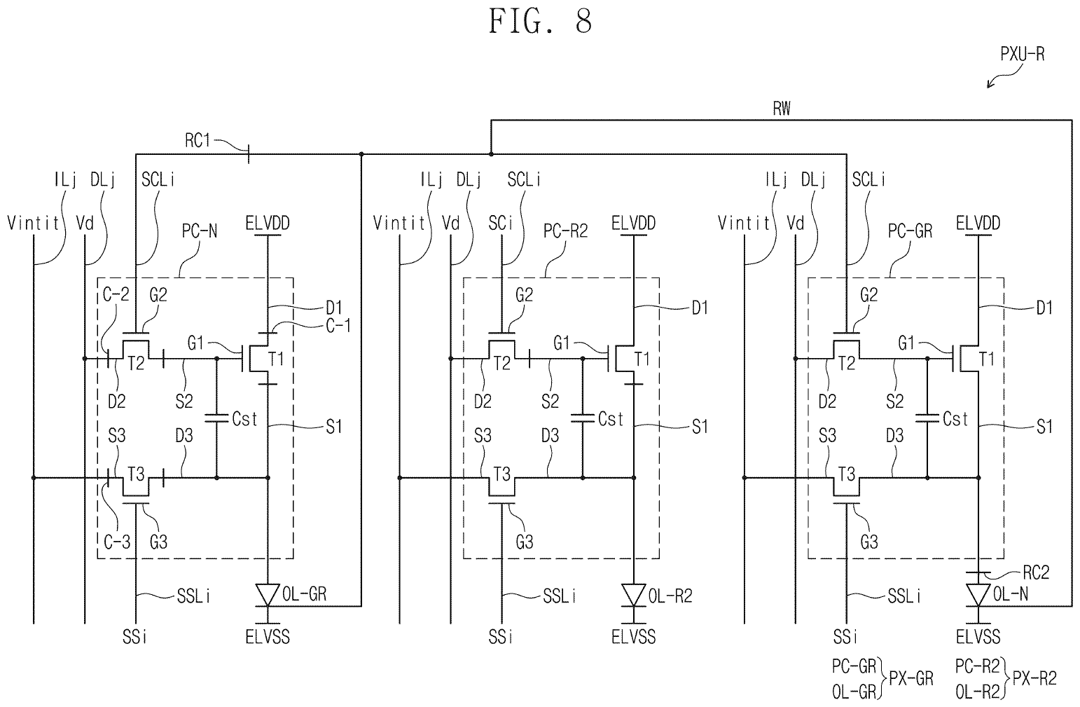

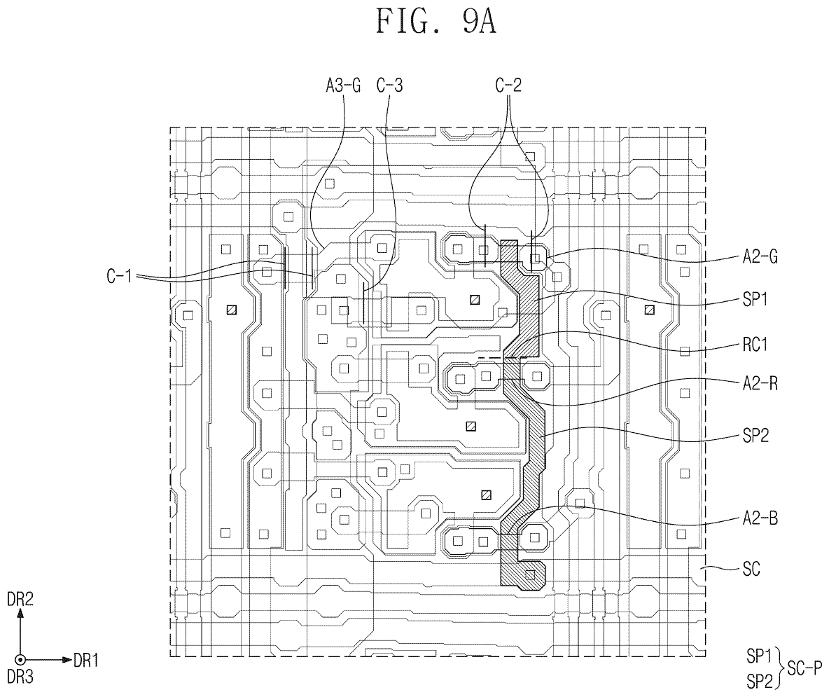

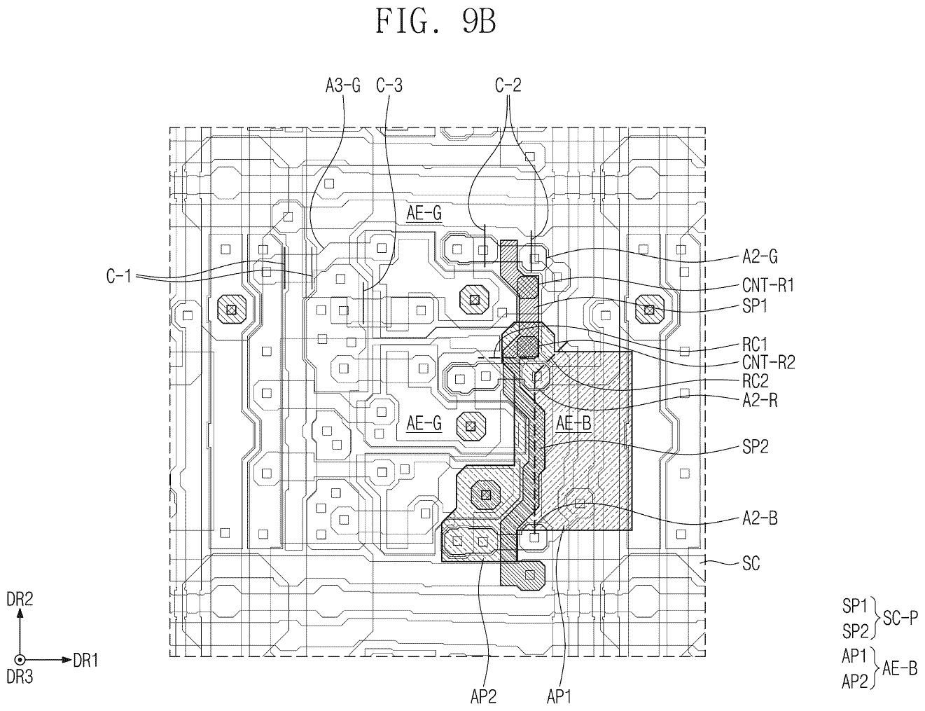

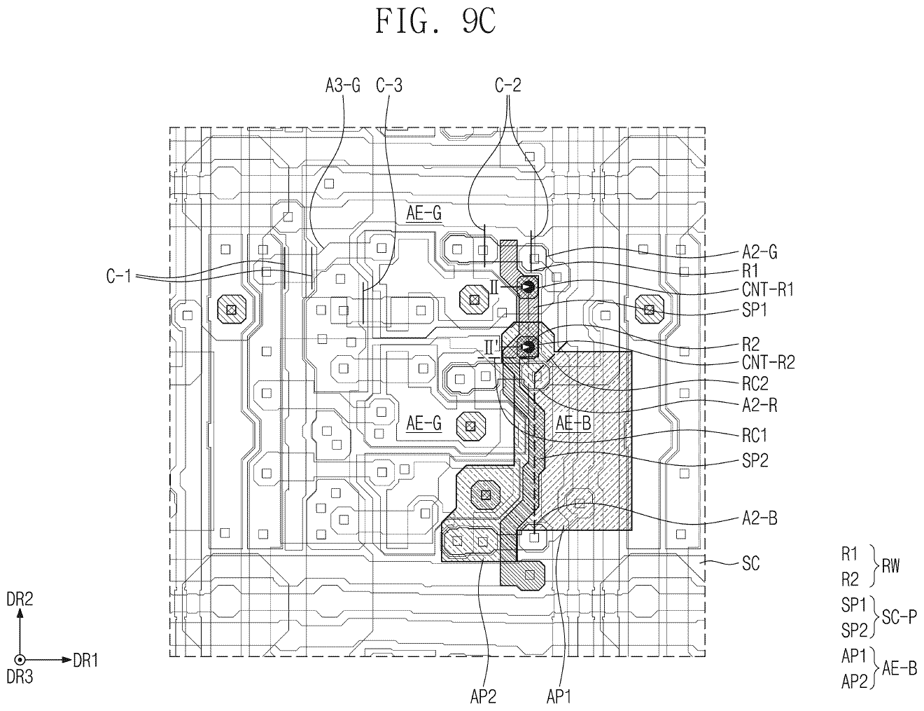

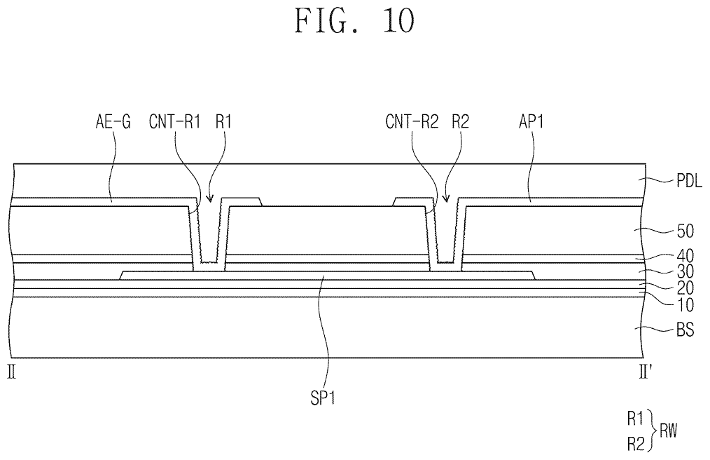

FIG. 8 is an equivalent circuit diagram illustrating a repair process of one pixel included in a unit pixel according to one or more embodiments of the present disclosure. FIGS. 9A to 9C are plan views illustrating a repair process of conductive patterns included in a unit pixel according to one or more embodiments of the present disclosure. FIG. 10 is a cross-sectional view taken along the line II-II′ of FIG. 9C.

FIG. 8 illustrates equivalent circuit diagrams of pixels PX-R2 and PX-GR included in the repair unit pixel PXU-R described with reference to FIG. 4B. The repair unit pixel PXU-R may include a repair pixel PX-GR, a second normal pixel PX-R2, a disconnection pixel circuit PC-N, and a disconnection light-emitting element OL-N. Any one of the pixels included in the normal unit pixel PXU-N (see FIG. 4B) may emit source light after being repaired from a defective state. Semiconductor patterns included in a pixel circuit of a defective pixel may be disconnected.

For example, in the disconnection pixel circuit PC-N, semiconductor patterns included in first to third transistors T1, T2, and T3 may be disconnected C-1, C-2, and C-3. In this specification, the wording “disconnection” may mean a state in which one component is physically/electrically disconnected.

A repair process according to the present disclosure may include an operation of disconnecting a scan pattern SC-P (see FIG. 7C) included in the repair unit pixel PXU-R (RC1), an operation of disconnecting a first electrode included in the disconnection light-emitting element OL-N (RC2), and an operation of connecting a repair light-emitting element OL-GR to a repair pixel circuit PC-GR (RW). Hereinafter, a method of repairing a display panel according to one or more embodiments of the present disclosure will be described in detail with reference to FIGS. 9A to 9C.

A method of repairing a display panel according to the present disclosure may include an operation of forming first to third pixel circuits each having first to third transistors, an operation of forming a scan line having a scan pattern which overlaps semiconductor patterns included in the second transistors, an operation of checking signals of the first to third pixel circuits, an operation of disconnecting semiconductor patterns included in the first to third transistors of the first pixel circuit, an operation of performing disconnection to divide the scan pattern into a first pattern overlapping the second transistor of the first pixel circuit and a second pattern overlapping the second transistors of the second and third pixel circuits, an operation of forming an organic insulating layer for covering the first to third pixel circuits, an operation of forming first and second repair holes in the organic insulating layer that overlap the first pattern, an operation of forming first electrodes that overlap the first to third pixel circuits on the organic insulating layer, an operation of performing disconnection to divide the first electrode overlapping the third pixel circuit into a first portion connected to the third pixel circuit and a second portion spaced apart from the third pixel circuit, and an operation of connecting the first electrode overlapping the first pixel circuit to the third pixel circuit. The operation of connecting the first electrode overlapping the first pixel circuit to the third pixel circuit may be performed by irradiating the first and second repair holes with a laser, and through the laser irradiation, the first electrode overlapping the first pixel circuit may be located in the first repair hole and connected to the first pattern, and the first portion may be located in the second repair hole and connected to the first pattern.

In addition, the method of repairing the display panel according to one or more embodiments may further include an operation of forming, on the organic insulating layer, a pixel-defining layer in which first to third openings for exposing at least a portion of each of the first electrodes are defined. Here, a boundary between the first portion and the second portion may be formed along one side of the third opening that overlaps the third pixel circuit on a plane. Then, an operation of forming, on the first electrodes, a common layer and a second electrode may further be included.

FIG. 9A illustrates a state in which the first to fourth insulating layers 10, 20, 30, and 40 and the first to fourth conductive layers MSL1, MSL2, MSL3, and MSL4, described with reference to FIGS. 7A to 7F, are formed.

The operation of checking the signals of the first to third pixel circuits may be performed after the fourth insulating layer 40 is formed. When a defect, such as a short-circuit defect occurs in the first pixel circuit among the first to third pixel circuits, the semiconductor patterns included in the first pixel circuit may be disconnected C-1, C-2, and C-3 through a laser process.

Then, the operation of disconnecting the scan pattern SC-P (RC1) may be performed. The scan pattern SC-P may be disconnected such that scan pattern SC-P is divided into a first pattern SP1 overlapping the second active pattern A2-G of the first pixel circuit, and a second pattern SP2 overlapping the second active patterns A2-R and A2-B of the second and third pixel circuits. The operation of disconnecting the scan pattern SC-P (RC1) may be performed through a laser process.

Then, referring to FIG. 9B, the method may include the operation of forming the fifth insulating layer 50 (the organic insulating layer), which is described with reference to FIG. 7G. Thereafter, the method may include the operation of forming, in the fifth insulating layer 50 (the organic insulating layer), first and second repair holes CNT-R1 and CNT-R2, which overlap the first pattern SP1, and are spaced apart from each other along the second direction DR2. The first and second repair holes CNT-R1 and CNT-R2 may be formed through a laser process. Forming the first and second repair holes CNT-R1 and CNT-R2 in advance enables connection of the first electrode overlapping the first pixel circuit to the first pattern and connection of the first pattern to a first portion of the disconnected first electrode, in a later process.

Thereafter, the method may include the operation of forming the first electrodes AE-G, AE-R, and AE-B on the fifth insulating layer 50 and the operation of disconnecting the first electrode AE-B overlapping the third pixel circuit. The first electrode AE-B may be disconnected such that the first electrode AE-B is divided into a first portion AP1 and a second portion AP2 through a laser process. The first portion AP1 may be connected to the third pixel circuit and the second portion AP2 may be spaced apart from the third pixel circuit. On a plane, a boundary between the first portion AP1 and the second portion AP2 may be formed along one side of the opening OP (see FIG. 6) which is formed in the pixel-defining layer PDL. For example, the boundary between the first portion AP1 and the second portion AP2 may be formed on the basis of one long side of the opening OP (see FIG. 6) extending along the second direction DR2.

Then, referring to FIGS. 9C and 10, the method may include the operation of connecting the repair light-emitting element OL-GR to the repair pixel circuit PC-GR (RW). Thus, the first electrode AE-G overlapping the first pixel circuit may be connected to the first pattern SP1 by irradiating the first repair hole CNT-R1 with a laser, and the first portion AP1 may be connected to the first pattern SP1 by irradiating the second repair hole CNT-R2 with a laser.

When the first repair hole CNT-R1 is irradiated with a laser, the first electrode AE-G overlapping the first pixel circuit may be melted inside the first repair hole CNT-R1 and connected to one end of the first pattern SP1. When the second repair hole CNT-R2 is irradiated with a laser, the first portion AP1 may be melted inside second repair hole CNT-R2 and connected to the other end of the first pattern SP1. Accordingly, the repair light-emitting element OL-GR, which includes the first electrode AE-G overlapping the first pixel circuit, may be connected to the repair pixel circuit PC-GR, which is connected to the first portion AP1, and may thus be normally operated.

In a method of repairing a display panel according to the present disclosure, repair holes are formed in an organic insulating layer in advance, and therefore a later process for connecting a repair pixel circuit to a repair light-emitting element may proceed. Consequently, a display panel repairing method with improved repair process efficiency and reduced costs may be provided.

According to one or more embodiments of the present disclosure, because repair holes are formed in an organic insulating layer in advance, a later process for connecting a repair pixel circuit to a repair light-emitting element may proceed. Thus, a display panel repairing method in which the quality of the repaired display panel and repair process efficiency are improved and for which costs are reduced may be provided.

In the above, description has been made with reference to embodiments of the present disclosure, but those skilled in the art or those of ordinary skill in the relevant technical field may understand that various modifications and changes may be made to the present disclosure within the scope not departing from the spirit and the technology scope of the present disclosure described in the claims to be described later. Therefore, the technical scope of the present disclosure is not limited to the contents described in the detailed description of the specification, but should be determined by the claims, with functional equivalents thereof to be included therein.

What is claimed is:

1. A display panel comprising:
a base layer;
data lines above the base layer, arranged along a first direction, and extending along a second direction crossing the first direction;
a first power supply line extending along the first direction;
a sensing line spaced apart from the first power supply line in the second direction, and extending along the first direction;
a first pixel circuit, a second pixel circuit, and a third pixel circuit comprising a first transistor, a second transistor, and a third transistor comprising semiconductor patterns, at least one of the semiconductor patterns of the first pixel circuit being disconnected;
a scan line spaced apart from the sensing line in the second direction with the first pixel circuit, the second pixel circuit, and the third pixel circuit therebetween, and extending along the first direction;
a first light-emitting element overlapping the first pixel circuit, and connected to the third pixel circuit;
a second light-emitting element overlapping the second pixel circuit and connected to the second pixel circuit; and
a third light-emitting element overlapping the data lines, and disconnected from the third pixel circuit.

2. The display panel of claim 1, wherein the third light-emitting element is disconnected from the first pixel circuit and the second pixel circuit, and is not configured to emit light, and
wherein the first light-emitting element and the second light-emitting element are configured to emit light.

3. The display panel of claim 1, wherein the first light-emitting element, the second light-emitting element, and the third light-emitting element comprise a first electrode, a second electrode above the first electrode, and a common layer between the first electrode and the second electrode, and
wherein the common layer and the second electrode are commonly located in the first light-emitting element, the second light-emitting element, and the third light-emitting element.

4. The display panel of claim 3, further comprising a pixel-defining layer above the base layer, and defining openings exposing the first electrodes and comprising a first opening defining a first light-emitting region, a second opening defining a second light-emitting region, and third opening defining a third light-emitting region.

5. The display panel of claim 4, wherein the first electrode of the third light-emitting element is disconnected.

6. The display panel of claim 5, wherein, in plan view, the first electrode of the third light-emitting element is disconnected and divided into a first portion and a second portion extending in the second direction along one long side of the third opening,
wherein the first portion is connected to the third pixel circuit, and
wherein the second portion is disconnected from the third pixel circuit.

7. The display panel of claim 6, wherein the scan line comprises a scan pattern along the second direction and overlapping one of the semiconductor patterns in the second transistor.

8. The display panel of claim 7, wherein the scan pattern comprises a first pattern overlapping the second transistor of the first pixel circuit, and a second pattern disconnected from the first pattern and overlapping the second transistor of the second pixel circuit and the second transistor of the third pixel circuit.

9. The display panel of claim 8, wherein one end of the first portion is connected to the first pattern via a first repair hole in the first pattern, and
wherein the first electrode of the first light-emitting element is connected to the first pattern via a second repair hole spaced apart from the first repair hole.

10. The display panel of claim 9, wherein the first electrode of the first light-emitting element is connected to the third pixel circuit via the first pattern and the first portion.

11. The display panel of claim 10, further comprising a light control layer above the first light-emitting element, the second light-emitting element, and the third light-emitting element,
wherein the light control layer comprises color control layers comprising quantum dots, and color patterns above the color control layers.

12. The display panel of claim 11, wherein the first light-emitting element is configured to generate light to pass through the light control layer to provide blue light, and
wherein the second light-emitting element is configured to generate light to pass through the light control layer to provide green light.

13. A method of repairing a display panel, the method comprising:
forming a first pixel circuit, a second pixel circuit, and a third pixel circuit comprising a first transistor, a second transistor, and a third transistor;
forming a scan line comprising a scan pattern overlapping semiconductor patterns in the second transistor;
checking signals of the first pixel circuit, the second pixel circuit, and the third pixel circuit;
disconnecting semiconductor patterns in the first transistor, the second transistor, and the third transistor of the first pixel circuit;
dividing the scan pattern into a first pattern overlapping the second transistor of the first pixel circuit, and a second pattern overlapping the second transistor of the second pixel circuit and the second transistor of the third pixel circuit;
forming an organic insulating layer covering the first pixel circuit, the second pixel circuit, and the third pixel circuit;
forming, in the organic insulating layer, a first repair hole and a second repair hole overlapping the first pattern;
forming first electrodes overlapping the first pixel circuit, the second pixel circuit, and the third pixel circuit on the organic insulating layer;
dividing the first electrode overlapping the third pixel circuit into a first portion connected to the third pixel circuit, and a second portion spaced apart from the third pixel circuit; and
connecting the third pixel circuit to the first electrode overlapping the first pixel circuit.

14. The method of claim 13, wherein the connecting the third pixel circuit to one of the first electrodes overlapping the first pixel circuit comprises irradiating the first repair hole and the second repair hole with a laser.

15. The method of claim 14, wherein the one of the first electrodes overlapping the first pixel circuit is in the first repair hole and is connected to the first pattern, and
wherein the first portion is in the second repair hole and is connected to the first pattern.

16. The method of claim 13, further comprising forming on the organic insulating layer a pixel-defining layer defining a first opening, a second opening, and a third opening respectively exposing portions of the first electrodes.

17. The method of claim 16, wherein a boundary between the first portion and the second portion is formed along one side of the third opening overlapping the third pixel circuit in plan view.

18. The method of claim 17, further comprising:
forming a common layer on the first electrodes; and
forming a second electrode on the common layer.

19. The method of claim 17, wherein the first opening overlapping one of the first electrodes connected to the third pixel circuit is configured to emit light,
wherein the second opening overlapping another one of the first electrodes connected to the second pixel circuit is configured to emit light, and
wherein the third opening overlapping an additional one of the first electrodes overlapping the third pixel circuit is not configured to emit light.

20. The method of claim 19, wherein the second opening and the third opening are spaced apart from each other along a first direction in which the scan line extends, and
wherein the first opening is spaced apart from the second opening along a second direction crossing the first direction.
